(19) United States
(12) Patent Application Publication
(10) Pub. No.: US 2002/0070450 A1
(43) Pub. Date: Jun. 13, 2002

(54) Bond pad structure for integrated circuits

(76) Inventor: Samuel McKnight, New Paltz, NY (US)

Correspondence Address: Tiffany Townsend, IBM Corporation - Intellectual Property, 2070 Route 52, Hopewell Junction, NY, 12533, US

(21) Appl. No.: 09/731,618

(22) Filed: Dec. 7, 2000

(51) Int. Cl. H01L 23/48; H01L 23/52; H01L 29/40

(52) U.S. Cl. 257/737

(57) ABSTRACT

A bond pad structure for an integrated circuit has a bond pad with an operational bonding area for receiving a bonded wire thereon. A test probe contacting area, extends from the operational bonding area, with the test probe contact area being electrically contiguous with the operational bonding area. In a preferred embodiment of the invention, the test probe contacting area has a surface area which is less than the surface area corresponding to the operational bonding area.

### BACKGROUND OF THE INVENTION

The invention relates to integrated circuits and, more particularly, to a bond pad structure applicable to the manufacture and testing of integrated circuits.

The application of test probes to metallic bond pads is commonplace during the testing of newly manufactured semiconductor chips. Existing probing techniques typically involve placing a needle-like probe surface to the same area of the bond pad in which a permanent interconnection interface (bond) is to be subsequently located. These resulting probe marks can actually displace a portion of the metallic material forming the pad, in some instances creating a void or cavity at the location of probe impact. This kind of mechanical damage inflicted upon a bond pad can adversely impact the integrity of a subsequent bond made between a connecting wire and the bond pad surface.

One solution offered in the prior art is to simply extend the area of a generally rectangular bond pad such that there is room enough on the pad to locate the permanent bond away from any cavity or void created by a test probe. This solution becomes increasingly difficult, however, the size of bond pad structures overall continues to decrease in response to miniaturization of semiconductor devices. As such, the surface area of bond pad structures are approaching the diameters of the ball bonds themselves.

Accordingly, it is desirable to have an efficiently configured bond pad structure which accommodates the application of test probes, but which also preserves a relatively intact bonding surface for a wire connection to be bonded thereto.

### SUMMARY OF THE INVENTION

In an exemplary embodiment of the invention, a bond pad structure for an integrated circuit has a bond pad with an operational bonding area for receiving a bonded wire thereon. A test probe contacting area, extends from the operational bonding area, with the test probe contact area being electrically contiguous with the operational bonding area. In a preferred embodiment of the invention, the test probe contacting area has a surface area which is less than the surface area corresponding to the operational bonding area.

A series of bond pads is formed upon an integrated circuit, such that the operational bonding area of one of the bond pads is adjacent to the test probe contacting area of another of the bond pads.

### BRIEF DESCRIPTION OF THE DRAWINGS

FIG. 1 is a side cross sectional view of a wire which has been ball bonded to a prior art bond pad structure;

FIG. 2 is a side cross sectional view of a wire which has been ball bonded to a bond pad structure in accordance with an embodiment of the invention;

FIG. 3 is a top view of a series of bond pad structures in accordance with an embodiment of the invention;

FIG. 4 is a perspective view of two pairs of bond pad structures shown in FIG. 3, illustrating the insertion of a pair of probes and a pair of wire, respectively therein; and

FIG. 5 is a bottom perspective view of a pair of bond pad structures in accordance with an embodiment of the invention, along with a pair of prior art bond pad structures for comparison thereto.

### DETAILED DESCRIPTION OF THE PREFERRED EMBODIMENT

FIG. 1 illustrates a prior art bond pad configuration 10 disposed within an integrated circuit substrate layer 11. A bond pad 12 is comprised of a conducting material having generally rectangular configuration. During the manufacturing and testing of an integrated circuit, a probe (not shown) is brought into contact with the surface 13 of bond pad 12. As described earlier, the probe can often cause mechanical damage to the surface 13 of pad by creating a cavity 14 or indentation on the surface. The material displaced by the force of the probe may in some instances be forced outward to form a ridge 16 on the surface 13 of the bond pad 12. The combination of the ridge 16 and the cavity 14 formed by probing (as well as the potential for contamination deposited on the bonding surface 13), can adversely impact the effectiveness of a wire bond, which is typically made to the same area of the bond pad disturbed by the probe. As seen in FIG. 1, wire 16 is ball bonded to the surface 13 of bond pad in the cavity 14 region.

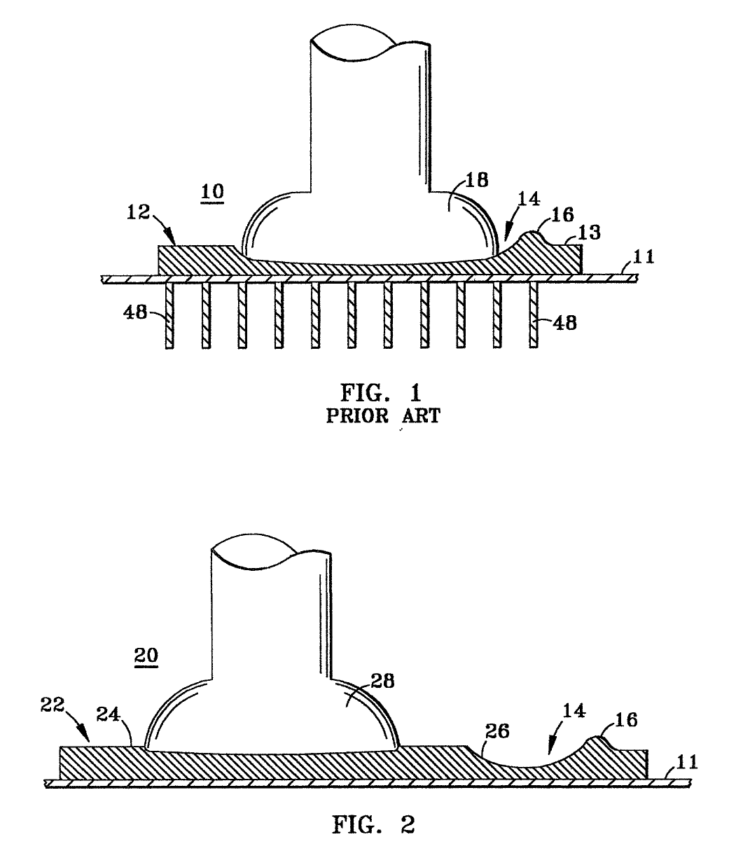

Referring now to FIGS. 2-4, a bond pad structure 20 representing an embodiment of the present invention is disclosed. Bond pad structure 20 comprises a bond pad 22, which is a block of electrically conducting, bondable material such as aluminum, and features both an operational bonding area 24 and a test probe contacting area 26. The operational bonding area 24 is intended to receive a wire 28 to be bonded thereon. The test probe contacting area 26 is intended to receive a test probe 30 (FIG. 4) thereon, and extends from the operational bonding area 24 such that it is electrically contiguous thereto. It will be noted from FIG. 2 that the wire 28 is shown bonded to the operational bonding area 24 and not the test probe contacting area 26, upon which a cavity 14 and ridge 16 have been formed by test probing.

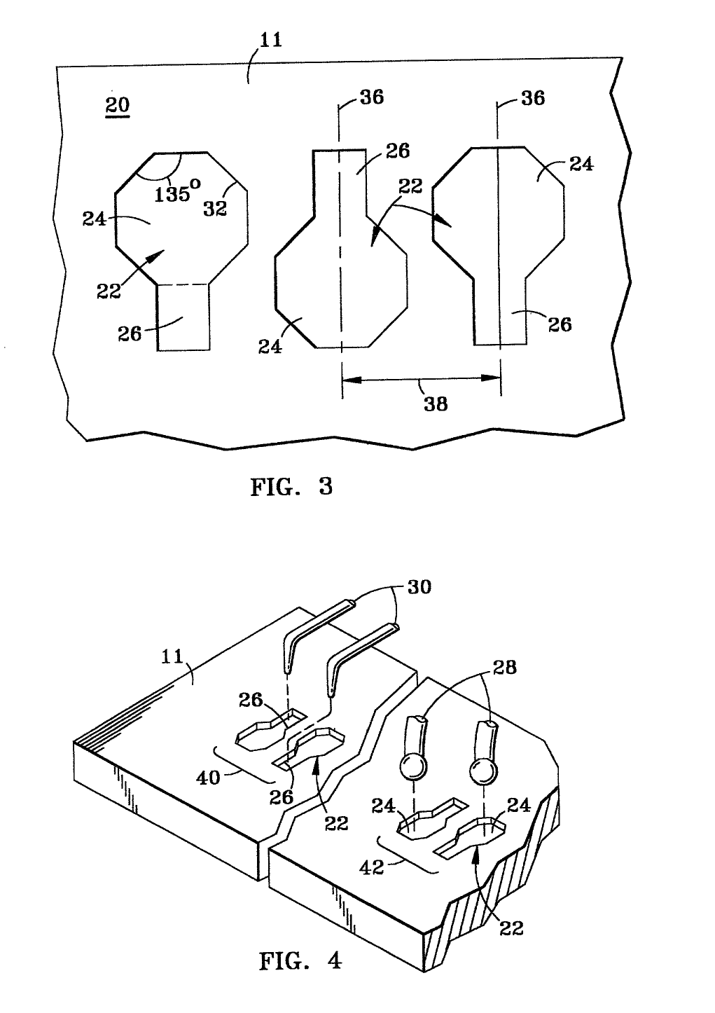

As is best seen in FIG. 3, the operational bonding area 24 is generally octagonally shaped. Each wall 32 of the operational bonding area 24 is at an approximate 135° angle with respect to one another. This configuration is compatible with known masking, deposition and etching techniques. Other embodiments, however, are also contemplated for the operational bonding area 24, such as square, hexagonal, polygonal or circular shapes. The test probe contacting area 26 is generally rectangular shaped, having an overall surface area less than the surface area of the operational bonding area 24. Since the area of the probing surface 34 of a test probe 30 is generally smaller than that of a ball or other wire tip, less space is needed for the test probe contacting area 26.

FIG. 3 also illustrates a series of bond pads 22, according to an embodiment of the invention. Each pad 22 is disposed next to one another such that the centerline, or longitudinal axis 36 of each pad is oriented in a parallel configuration. Further, the bond pads 22 are alternatingly “flip-flopped” such that the operational bonding area 24 of one bond pad is directly adjacent the test probe contacting area 26 of a neighboring bond pad. In this manner, more efficient spacial use is made of the circuit substrate 11, thereby reducing the effective pitch 38 of the device. The pitch 38 is defined by the distance between longitudinal axes 36 of adjacent bond pads 22.

FIG. 4 illustrates two pairs of bond pads 22, with one pair 40 showing the location of the insertion of the test probe needles 30 onto the test probe contacting area 26. The other pair 42 of bond pads 22 show the location of the insertion of the wires 18 onto the operational bonding area 24.

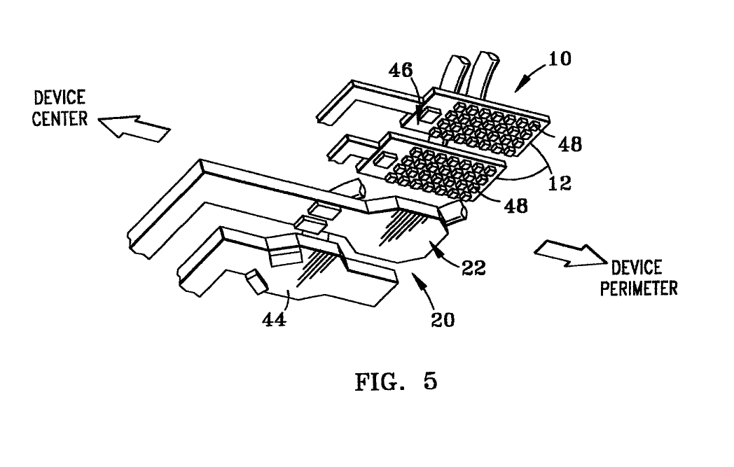

A perspective view of the bottom surface 44 of the bond pad structure 20 of FIGS. 2-4, as compared to the bottom surface 46 of a prior art structure 10, is shown in FIG. 5. The pair of prior art bond pads 12 are included with an array of support structures 48, or vias which support the pads from underneath. Support structures 48 support the prior art bond pads 12 from mechanical stresses introduced by both wire bonding and probe testing. As such, the structures 48 are uniformly spaced throughout the entire bottom surface 46 of the prior art pads 12. In contrast, there are no support structures 48 directly supporting the bottom surface 44 of the pads 22 underneath the operational bonding area 24.

Several advantages are realized by the aforementioned embodiment of a bond pad structure 20. First, the physical separation between the operational bonding area 24 and the test probe contacting area 26 allows the probe testing to take place without compromising the integrity of the operational bonding area 24, thereby reducing the likely occurrence of bonding failures. The particular configuration of the bond pads 22, such that the operational bonding area 24 of one bond pad 22 is directly adjacent the probe contact area of the neighboring pad or pads, reduces the effective in line bond pad pitch or spacing between neighboring bond pads 12.

In addition, the reduced amount of mechanical stress placed upon the operational bonding area 24 (from the absence of probe contact) permits the reduction or elimination of pad support structures 48 directly underneath the operational bonding area 24. The reduction of pad support structures 48, in turn, permits additional interconnections or conduits (not shown) to be located beneath the bond pad structure 20.

Another advantage of the present embodiment is the flexibility with regard to the selection of bonding materials used in the wire bonding process. For example, gold is typically the bonding metal of choice because of its resistance to oxidation. On the other hand, copper bond wire has certain advantages over gold, such as lower bulk resistivity and a higher modulus of elasticity. A stiffer bonding metal, such as copper, would allow for longer lengths of wire to be used in the wire bonding process. The bond pad layout structure as embodied in the invention, provides efficient and close packing of individual bond pads. Thus, more rows of bond pads may be located within a given area of a circuit substrate. The additional rows of bond pads will facilitate the longer lengths of bond wire, which should be stiffer. Still another advantage to copper wire is the ability to use a smaller diameter copper wire than that of gold. Correspondingly, the diameter of the copper ball bond may be smaller than that of gold. In turn, a smaller ball bond allows for smaller bond pad 22 and, accordingly a reduced pitch 38 therebetween (FIG. 3). In one embodiment of the invention, the pitch 38 may be reduced to below 50 microns (μM). Copper, therefore, is a desired alternative bonding metal to gold.

While the invention has been described with reference to a preferred embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment or embodiments disclosed as the best mode contemplated for carrying out this invention, but that the invention will include all embodiments falling within the scope of the appended claims.

1. A bond pad structure for an integrated circuit, said bond pad structure comprising:
a bond pad having an operational bonding area for receiving a bonded wire thereon; and
a test probe contacting area, extending from said operational bonding area, said test probe contact area electrically contiguous with said operational bonding area;
said test probe contacting area further having a first surface area which is less than a second surface area, said second surface area corresponding to said operational bonding area.

2. The bond pad structure of claim 1, wherein said operational bonding area is octagonal shaped.

3. The bond pad structure of claim 2, wherein said operational bonding area further comprises a plurality of walls, said walls forming an octagonal shape.

4. The bond pad structure of claim 3, wherein one of said plurality of walls abuts another of said plurality of walls at a 135° angle.

5. The bond pad structure of claim 1, wherein said bonded wire is comprised of copper.

6. The bond pad structure of claim 1, further comprising a series of bond pads formed upon an integrated circuit, wherein said operational bonding area of one of said bond pads is adjacent to said test probe contacting area of another of said bond pads.

7. The bond pad structure of claim 6, wherein a longitudinal axis of said one of said bond pads is parallel to another longitudinal axis of said another of said bond pads.

8. The bond pad structure of claim 7, wherein the distance between said longitudinal axis of said one of said bond pads and said another longitudinal axis of said another of said bond pads is less than 50 microns.
